(19) United States
(12) Patent Application Publication
(10) Pub. No.: US 2021/0378079 A1
(43) Pub. Date: Dec. 2, 2021

(54) FLUID DESTATICIZER

(71) Applicants: Hsao-Szu Chang, Miaoli County (TW); Marketech International Corp., Taipei City (TW)

(72) Inventors: Ping-Hsu CHEN, Taichung City (TW); Chien-Kuo LU, Hsinchu City (TW); Hsao-Szu CHANG, Miaoli County (TW)

(21) Appl. No.: 17/089,740

(22) Filed: Nov. 5, 2020

(30) Foreign Application Priority Data
Jun. 2, 2020 (TW) 109118486

(51) Int. Cl. H05F 3/02; H05K 9/00

(52) U.S. Cl. CPC H05F 3/02; H05K 9/0067

(57) ABSTRACT

A fluid destaticizer includes a valve main body, a one-way check valve, a discharge vessel, and an electrostatic discharger. The one-way check valve is installed in the valve main body, the discharge vessel is provided in the valve main body, and the discharge vessel is connected to the one-way check valve. In addition, the discharge vessel includes a sidewall, and the electrostatic discharger is installed on the sidewall of the discharge vessel to discharge the electrostatic charge in the fluid and the fluid is exhausted from the valve main body through the discharge vessel.

### RELATED APPLICATIONS

This application claims priority to Taiwan Application Serial Number 109118486, filed Jun. 2, 2020, which is herein incorporated by reference.

### TECHNICAL FIELD

The present disclosure generally relates to a destaticizer. More particularly, the present disclosure relates to a fluid destaticizer.

### BACKGROUND

Static electricity is a phenomenon in the nature, and when an object with static electricity comes in contact with an object with a potential difference, electric charge transfer may occur and result in spark discharge.

Since two different substances rub against each other, contact, and separate and electrify, static electricity may be generated. In severe cases, the surrounding flammable material may be ignited, and a fire or explosion may therefore occur. Accordingly, the static electricity problem and the harm caused by the static electricity have attracted more and more attention. In the chemical, petroleum, coatings, plastics, printing and electronics industries, potential electrostatic hazards are prone to accidents, which can cause casualties and property losses.

In the industrial production process, static electricity may be generated with various operations, such as tearing, peeling, pulling, impacting, crushing, screening, rolling, stirring, conveying, spraying and filtering materials, as well as gas and liquid flow, splashing, spraying, etc. If static electricity accumulates to a dangerous level, electrostatic discharge may occur. The fundamental reason that static electricity can cause various hazards is that the electrostatic discharge sparks have the energy to ignite the surrounding material. When the spark energy generated by the electrostatic discharge is greater than the minimum ignition energy (MIE) required by the explosive mixture, the spark energy may cause a fire or an ignition source of the explosion.

According to the statistics of the research report database of the Institute of Labor Safety and Health, the petrochemical industry has the highest fire or explosion hazard, followed by the chemical materials industry and chemical products manufacturing industries. The main reason is that most of the liquids, gases and other substances utilized in the petrochemical industry and the chemical industry are flammable. Therefore, the proportions of the electrostatic hazard accidents in the three industries are higher the other industries.

Case 1: At about 13:00 on Oct. 29, 2007, a fire and a series of explosions occurred in a chemical storage and transportation site in Iowa, USA. At that moment, Ethyl acetate was being injected into 300-gallon tanks to sub-pack the Ethyl acetate, the operator used a synthetic rubber hose to transport the solvent to the top of the tanks, and immediately heard the explosion sound. The fire extended to a warehouse and ignited other flammable and combustible liquids stored in the warehouse. Hence, an employee was slightly injured, and 1 firefighter was burned.

Case 2: At about 14:00 on Nov. 11, 2008, a fire and explosion accident occurred in a waterproof coating company in Taoyuan County, Taiwan. At the time of the accident, the solvent-based coating production process was in progress. The organic solvent toluene and the paint solvent are mixed and stirred with paint raw materials. When the bottom toluene tank was pumped by air pressure to inject the toluene solvent into an inlet above the stirring tank, a fire and explosion accident occurred suddenly, and one of two on-site operators died and the other one suffered severe burns.

According to cases at home and abroad, if the problem of static electricity cannot be overcome when chemical liquid is transported, the static electricity can cause very serious consequences. Therefore, there is a need to safely and reliably transport the chemical solvents to reduce the occurrence of accidents and help improve the production safety.

### SUMMARY

One objective of the embodiments of the present invention is to provide a fluid destaticizer able to conveniently install in a fluid pipeline and immediately discharge the electrostatic charge accumulated in the fluid pipeline, and the fluid in contact with a metal is discharged at the same time to avoid contamination of the subsequent manufacturing process.

To achieve these and other advantages and in accordance with the objective of the embodiments of the present invention, as the embodiment broadly describes herein, the embodiments of the present invention provides a fluid destaticizer including a valve main body, a one-way check valve, a discharge vessel and an electrostatic discharger. The one-way check valve is installed in the valve main body, the discharge vessel is disposed in the valve main body, the discharge vessel is connected to the one-way check valve and the discharge vessel includes a sidewall. The electrostatic discharger is installed on the sidewall of the discharge vessel to discharge an electrostatic charge in a fluid and the fluid is exhausted from the valve main body through the discharge vessel.

In some embodiments, the one-way check valve includes a piston and a spring, and the piston compresses the spring to allow the fluid flowing to the discharge vessel when a pressure of the fluid is larger than a predetermined value.

In some embodiments, the piston is a perfluoroalkoxy alkanes (PFA) piston, and the valve main body is a PFA valve main body.

In some embodiments, the spring is a PFA spring.

In some embodiments, the spring is a metal spring with a PFA coating.

In some embodiments, the valve main body includes a connecting portion connected to a connecting section of a delivery pipe of a fluid delivery pipeline.

In some embodiments, the valve main body includes a discharge outlet connected to the discharge vessel to exhaust the fluid from the valve main body.

In some embodiments, the discharge outlet connects to an external discharge pipe.

In some embodiments, the electrostatic discharger includes an electrostatic discharging pin electrically connected to a ground terminal.

In some embodiments, the electrostatic discharging pin includes an noble metal electrostatic discharging pin.

Hence, the fluid destaticizer can automatically turn on according to the fluid pressure to discharge the electrostatic charge accumulating in the delivery pipe out of the delivery pipe. In addition, the piston, the spring and the valve main body can be made of the PFA material so as to effectively prevent the fluid from being contaminated by metal. Furthermore, the fluid in contact with the metal electrostatic discharger is directly discharged from the discharge outlet so as to further effectively avoid the pollution of the process fluid, thereby improving the production quality of the production line, further improving the safety of the fluid delivery, and greatly increasing the safety of the production process and the process yield.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 illustrates a schematic diagram showing a fluid destaticizer according to one embodiment of the present invention equipped in a fluid delivery pipeline;

FIG. 2 illustrates a simulation diagram showing an electrostatic charge accumulated in the fluid delivery pipeline while the fluid is delivering; and

FIG. 3 illustrates a simulation diagram showing the electrostatic charge in the fluid is discharged and the fluid is exhausted through the fluid destaticizer when the fluid is delivered in the fluid delivery pipeline.

### DETAILED DESCRIPTION OF THE PREFERRED EMBODIMENT

The following description is of the best presently contemplated mode of carrying out the present disclosure. This description is not to be taken in a limiting sense but is made merely for the purpose of describing the general principles of the invention. The scope of the invention should be determined by referencing the appended claims.

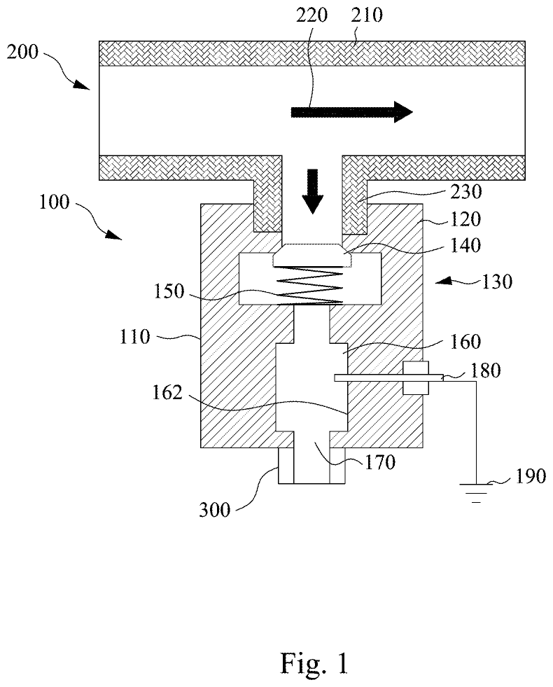

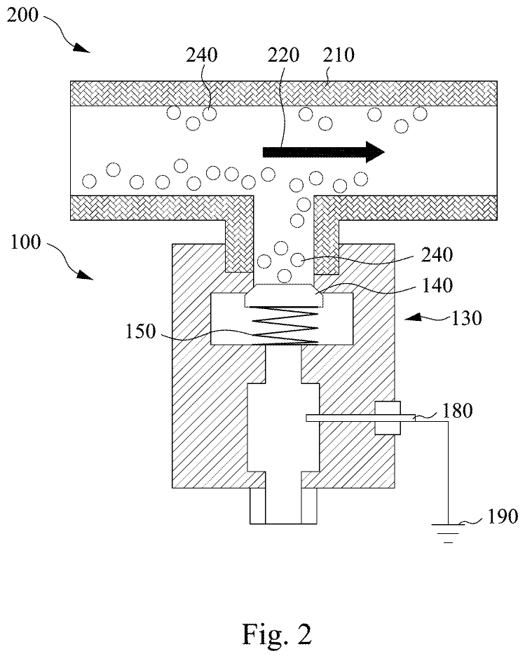

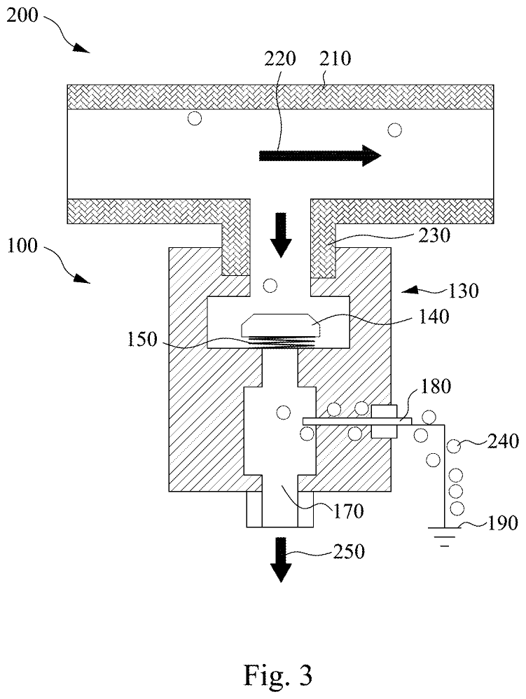

FIG. 1 illustrates a fluid destaticizer according to one embodiment of the present invention equipped in a fluid delivery pipeline, FIG. 2 illustrates the electrostatic charge accumulated in the fluid delivery pipeline while the fluid is delivering, and FIG. 3 illustrates the electrostatic charge in the fluid is discharged and the fluid is exhausted through the fluid destaticizer.

As shown in FIGS. 1, 2 and 3, the fluid destaticizer 100 includes a valve main body 110, a one-way check valve 130, a discharge vessel 160 and an electrostatic discharger 180.

The one-way check valve 130 is installed in the valve main body 110, the discharge vessel 160 is disposed in the valve main body 110, and the discharge vessel 160 connected to the one-way check valve 130. The electrostatic discharger 180 is installed on the sidewall 162 of the discharge vessel 160 to guide the electrostatic charge 240 of the fluid 220 outwardly and the discharge vessel 160 is utilized to exhaust the fluid 250 from the valve main body 110. Because the fluid 250 contacts the electrostatic discharger 180 made of the metal material, the fluid in contact with the electrostatic discharger 180 has to discharge from the fluid destaticizer 100 to prevent the subsequent manufacturing process from contamination.

In some embodiments, the valve main body 110 includes a connecting portion 120 connected to a connecting section 230 of a delivery pipe 210 in the fluid delivery pipeline 200. The connecting portion 120 can also be connected to any other elements, for example, a solenoid valve or a bypass line, in the fluid delivery pipeline 200 to discharge the electrostatic charge and the fluid from the fluid delivery pipeline 200 without departing from the spirit and the scope of the invention.

Furthermore, the valve main body 110 may further include a discharge outlet 170 connected to the discharge vessel 160 to discharge the fluid 220 from the valve main body 110. The discharge outlet 170 is utilized to connect to an external discharge pipe 300 to transport the fluid 250 to a fluid recycling tank.

In some embodiments, the electrostatic discharger 180 includes an electrostatic discharging pin electrically connected to a ground terminal 190 to guide the electrostatic charge in the fluid 220 to the ground terminal 190 so as to neutralize the electrostatic charge and prevent the electrostatic charge from accumulating in the delivery pipe 210.

In some embodiments, the delivery pipe 210 is a fluid delivery pipe made of perfluoroalkoxy alkanes (PFA) material.

In some embodiments, the fluid is a fluid used in factories such as chemical liquids, organic solvents, or slurries with solid particles.

In some embodiments, the one-way check valve 130 includes a piston 140 and a spring 150. When the pressure of the fluid is larger than a predetermined value, i.e. larger than 10 Kpa, the piston 140 may compress the spring 150 to allow the fluid flowing into the discharge vessel 160 and contacting to the electrostatic discharger 180 fixed on the sidewall 162 of the discharge vessel 160 so as to guide the electrostatic charge to the ground terminal 190 through the electrostatic discharger 180.

In addition, because the electrostatic discharger 180 is a pin type electrostatic discharger perpendicular to the sidewall 162 of the discharge vessel 160, the pin type electrostatic discharger 180 is perpendicular to the flowing direction of the fluid 250 to avoid the occurrence of fluid back splashing so as to prevent the fluid contacted the metal electrostatic discharger 180 from flowing back to the delivery pipe 210, thereby improving the quality and stability of the subsequent production process.

In some embodiments, the electrostatic discharging pin includes a noble metal electrostatic discharging pin which is made of noble metals with strong oxidation resistance and corrosion resistance, i.e. ruthenium, rhodium, palladium, silver, osmium, iridium, platinum and/or gold.

In some embodiments, the piston 140 is a perfluoroalkoxy alkanes (PFA) piston, and the valve main body 110 is a PFA valve main body.

In some embodiments, the spring 150 is a PFA spring, or a metal spring coated with a PFA coating layer to provide a suitable elasticity.

Accordingly, the fluid destaticizer can automatically turn on according to the fluid pressure to discharge the electrostatic charge accumulating in the delivery pipe out of the delivery pipe. In addition, the piston, the spring and the valve main body can be made of the PFA material so as to effectively prevent the fluid from the metal contamination. Furthermore, the fluid in contact with the metal electrostatic discharger is directly discharged from the discharge outlet so as to further effectively avoid the pollution of the process fluid, thereby improving the production quality of the production line, further improving the safety of the fluid delivery, and greatly increasing the safety of the production process and the process yield.

As is understood by a person skilled in the art, the foregoing preferred embodiments of the present invention are illustrative of the present invention rather than limiting of the present invention. It is intended that various modifications and similar arrangements be included within the spirit and scope of the appended claims, the scope of which should be accorded the broadest interpretation so as to encompass all such modifications and similar structures.

What is claimed is:

1. A fluid destaticizer, comprising:
a valve main body;
a one-way check valve installed in the valve main body;
a discharge vessel disposed in the valve main body, the discharge vessel connected to the one-way check valve, the discharge vessel comprising a sidewall; and
an electrostatic discharger installed on the sidewall of the discharge vessel to discharge an electrostatic charge in a fluid and the fluid is exhausted from the valve main body through the discharge vessel.

2. The fluid destaticizer of claim 1, wherein the one-way check valve comprises a piston and a spring, wherein the piston compresses the spring to allow the fluid flowing to the discharge vessel when a pressure of the fluid is larger than a predetermined value.

3. The fluid destaticizer of claim 2, wherein the piston is a perfluoroalkoxy alkanes (PFA) piston, and the valve main body is a PFA valve main body.

4. The fluid destaticizer of claim 3, wherein the spring is a PFA spring.

5. The fluid destaticizer of claim 3, wherein the spring is a metal spring with a PFA coating.

6. The fluid destaticizer of claim 1, wherein the valve main body comprises a connecting portion connected to a connecting section of a delivery pipe of a fluid delivery pipeline.

7. The fluid destaticizer of claim 1, wherein the valve main body comprises a discharge outlet connected to the discharge vessel to exhaust the fluid from the valve main body.

8. The fluid destaticizer of claim 7, wherein the discharge outlet connects to an external discharge pipe.

9. The fluid destaticizer of claim 1, wherein the electrostatic discharger comprises an electrostatic discharging pin electrically connected to a ground terminal.

10. The fluid destaticizer of claim 9, wherein the electrostatic discharging pin comprises a noble metal electrostatic discharging pin.
